(19) United States
(12) Patent Application Publication
(10) Pub. No.: US 2026/0304678 A1
(43) Pub. Date: Oct. 1, 2026

(54) PATCH PANEL FOR RECONFIGURABLE NETWORK TOPOLOGIES

(71) Applicant: Groq, Inc., Mountain View, CA (US)

(72) Inventor: Santosh Raghavan, Mountain View, CA (US)

(21) Appl. No.: 19/578,039

(22) Filed: Mar. 25, 2026

Related U.S. Application Data
(60) Provisional application No. 63/778,858, filed on Mar. 27, 2025.

(51) Int. Cl. H05K 7/14; G06F 1/186

(52) U.S. Cl. CPC H05K 7/1492; G06F 1/186

(57) ABSTRACT

An example apparatus can include a sliding patch panel. The sliding patch panel can include a plurality of first ports. The sliding patch panel can include a plurality of second ports. In the example apparatus, at least one respective second port of the plurality of second ports can be operatively connected to at least one corresponding first port of the plurality of first ports. In the example apparatus, the sliding patch panel can be configured to slide into and out of one or more slots.

### CROSS REFERENCE TO PRIORITY APPLICATION

The present disclosure claims the benefit of priority to U.S. Provisional Application Ser. No. 63/778,858, filed Mar. 27, 2025, the entirety of which is incorporated by reference herein.

### FIELD

The present disclosure relates generally to systems and methods for managing connections between computing devices and communication devices.

### BACKGROUND

In data centers and telecommunications systems, managing and reconfiguring optical connections between racks and within racks is a significant challenge. Active switches can be very expensive, while some passive patch panels may have other drawbacks, such as occupying significant rack height (especially for large port-count/radix of servers in the rack) or requiring extensive manual labor in high-temperature “hot aisles” of a data center when reconfiguring network topologies.

### SUMMARY

Aspects and advantages of embodiments of the present disclosure will be set forth in part in the following description, or can be learned from the description, or can be learned through practice of the embodiments.

Example aspects of the present disclosure provide an example apparatus. In some implementations, the example apparatus can include a sliding patch panel. The sliding patch panel can include a plurality of first ports. The sliding patch panel can include a plurality of second ports. In the example apparatus, at least one respective second port of the plurality of second ports can be operatively connected to at least one corresponding first port of the plurality of first ports. In the example apparatus, the sliding patch panel can be configured to slide into and out of one or more slots.

Example aspects of the present disclosure provide an example computing system. In some implementations, the example computing system can include a plurality of computing devices. The example computing system can include a rack configured to accept the plurality of computing devices. The example computing system can include a sliding patch panel configured to slide into and out of the rack. In the example computing system, the sliding patch panel can include a plurality of first ports and a plurality of second ports.

Example aspects of the present disclosure provide an example method. In some implementations, the example method can include sliding, from a slot in a server rack configured to hold a plurality of computing devices of the network of computing devices, a sliding patch panel. In the example method, the sliding patch panel can include a plurality of first ports and a plurality of second ports. In the example method, at least one port of the plurality of second ports can be operatively connected to one or more computing devices of the network of computing devices. The example method can include connecting or disconnecting at least one pair of first ports of the plurality of first ports.

These and other features, aspects, and advantages of various embodiments of the present disclosure will become better understood with reference to the following description and appended claims. The accompanying drawings, which are incorporated in and constitute a part of this specification, illustrate example embodiments of the present disclosure and, together with the description, explain the related principles.

### BRIEF DESCRIPTION OF THE DRAWINGS

Detailed discussion of embodiments directed to one of ordinary skill in the art is set forth in the specification, which refers to the appended figures, in which:

FIG. 1A depicts a first schematic diagram of an example server rack according to example implementations of aspects of the present disclosure;

FIG. 1B depicts a second schematic diagram of an example server rack according to example implementations of aspects of the present disclosure;

FIG. 2 depicts a top view of an example patch panel according to example implementations of aspects of the present disclosure;

FIG. 3 is a flow chart diagram of an example method for reconfiguring a network topology of a network of computing devices according to example implementations of aspects of the present disclosure;

FIG. 4 is a block diagram of an example multi-rack computing system according to example implementations of aspects of the present disclosure; and

FIG. 5 is a block diagram of an example processor device according to example implementations of aspects of the present disclosure.

### DETAILED DESCRIPTION

Example embodiments according to some aspects of the present disclosure are directed to systems and methods for reconfiguring a connection topology of a network of computing devices. More particularly, the present disclosure is directed to systems and methods for reconfiguring connection topologies using patch panels (e.g., optical patch panels) configured to slide into and out of a server rack.

A patch panel can include a plurality of first ports (e.g., optical ports) and a plurality of second ports, each second port operatively connected to a corresponding first port. The patch panel can be configured to slide in and out of a slot (e.g., server rack slot or another slot type such as a drawer slot, etc.).

In some instances, reconfiguring a connection topology of a network of computing devices can include reconfiguring connections between first ports of the plurality of first ports. For example, in some instances, a computing system can include a plurality of computing devices, and each computing device can be operatively connected to one or more second ports of the plurality of second ports. In such instances, a pair of computing devices can be connected or disconnected from each other by connecting or disconnecting a pair of first ports that are each connected to a second port connected to a computing device of the pair of computing devices.

In some instances, the first ports can be oriented in a manner to facilitate fast, low-cost, safe, or otherwise convenient access to the first ports. For example, in some instances, a sliding patch panel can be configured in a “pizza box” shape that can slide out horizontally, and the first ports can be located on a top side of the sliding patch panel, thereby facilitating fast and low-cost access to the first ports during a topology reconfiguration. As another example, in some instances, a computing system can be located in a server room comprising a plurality of “hot aisles” into which the computing devices exhaust hot air, and a plurality of “cold aisles” from which the computing devices intake cold air for cooling. In such instances, the sliding patch panel can be configured to slide out into a cold aisle (e.g., toward a side of a server rack associated with computing device air intakes; away from a side of the server rack associated with computing device exhausts; etc.), thereby facilitating safer, faster (e.g., due to a reduced need for cooling breaks or water breaks, etc.), or more ergonomic access to the first ports compared to some alternative implementations.

In some instances, a patch panel can comprise an optical patch panel, wherein the first ports and second ports are optical ports configured to receive optical connectors (e.g., fiber optic connectors; multi-fiber push on (MPO) connectors, Lucent Connectors (LC), standard connectors (SC), etc.), and each first port is connected to a corresponding second port via optical connection.

In some instances, an apparatus (e.g., sliding patch panel apparatus; server rack apparatus; etc.) can include various hardware to facilitate sliding the sliding patch panel. For example, in some instances, an apparatus can include slide hardware, such as roller hardware (e.g., wheels, etc.), drawer slides, track slides, or the like. As another example, in some instances, an apparatus can include frame hardware configured to accept the sliding patch panel, such as a drawer frame, cabinet frame, server slot frame, or the like. In some instances, a sliding patch panel or frame hardware configured to accept the sliding patch panel can be configured to fit inside a standard-sized server rack slot, such as a 1U, 2U, or other standard size (e.g., 3U, 4U, etc.) server slot. In some instances, a sliding patch panel can be configured to fit into frame hardware or a server rack slot with some additional clearance for fitting cables (e.g., fiber optic cables, etc.) connected to the first or second ports of the sliding patch panel. In some instances, an amount of clearance associated with the second ports can be larger than an amount of clearance associated with the first ports, as the first ports can in some instances be interconnected with low-profile short cables, while the second ports can be connected to computing devices (e.g., computing devices on a same or different server rack compared to the sliding patch panel, etc.) using cables long enough to facilitate sliding the patch panel into the cold aisle.

In some instances, a computing system can include a plurality of computing devices; a server rack; and a sliding patch panel configured to slide into and out of the server rack. In some instances, the computing system can further include a plurality of first cables connecting each of the plurality of second ports to a corresponding computing device of the plurality of computing devices. In some instances, the computing system can include a plurality of second cables connecting pairs of first ports of the plurality of first ports. In this manner, for instance, pairs of computing devices can be connected to each other (or disconnected, etc.) by connecting (or disconnecting) corresponding pairs of first ports, as each first port can be preconnected (e.g., permanently or semi-permanently connected) to a corresponding computing device via a corresponding second port.

In some instances, reconfiguring a connection topology of the computing system can include sliding out the sliding patch panel (e.g., into a cold aisle side of a server room); and reconfiguring one or more connections between the first ports (e.g., without reconfiguring any connections between the second ports and computing devices, etc.). In this manner, for instance, a connection topology of the computing system can be efficiently reconfigured. In some instances, reconfiguring connections between first ports can include one-pair-at-a-time reconfiguration using individual cables, or can include implementing a predetermined connection topology using a prebuilt quick-connect panel comprising a plurality of links (e.g., fiber optic cables) in a pattern corresponding to the predetermined connection topology.

Systems and methods according to some aspects of the present disclosure can provide a variety of technical effects and benefits, such as improvements to computing technology (e.g., patch panel technology; connection topology reconfiguration technology; etc.). For example, in some instances, systems and methods according to some aspects of the present disclosure can provide reduced vertical footprint of patch panels (e.g., high-port-count optical patch panels, etc.) compared to some alternative implementations. As another example, in some instances, systems and methods according to some aspects of the present disclosure can provide more efficient (e.g., faster, more ergonomic, safer, etc.) reconfiguration of a connection topology of a computing network compared to some alternative implementations. As another example, in some instances, systems and methods according to some aspects of the present disclosure can have a reduced cost compared to some alternative implementations (e.g., active optical switches, etc.).

In some instances, systems and methods according to some aspects of the present disclosure can provide reduced vertical footprint of patch panels (e.g., high-port-count optical patch panels, etc.). For example, some alternative patch panels can include vertically oriented panels fixedly attached to a hot side of a server rack. Although such implementations may be adequate for some low-port-count applications, a computing system having a high-radix connection topology may require a large amount of vertical rack for a large number of ports on the computing devices themselves, and may not have sufficient vertical rack space to also support a large number of vertically oriented patch panel ports. Advantageously, high-port-count patch panels according to some aspects of the present disclosure can be oriented horizontally (e.g., in a “pizza box” shape, etc.), and can in some instances fit into a 1U or 2U space of a server rack, thereby greatly reducing a vertical footprint of high-port-count patch panels compared to some alternative implementations.

In some instances, systems and methods according to some aspects of the present disclosure can provide more efficient (e.g., faster, more ergonomic, safer, etc.) reconfiguration of a connection topology of a computing network compared to some alternative implementations. For example, in some instances, sliding patch panels according to some aspects of the present disclosure can be configured to slide into an easily reached location (e.g., about waist height in a cold aisle of a data center, etc.), and first ports can be configured to be located on an easily reached side (e.g., top side, etc.) of the sliding patch panel, thereby increasing a speed at which a data center administrator can access and reconfigure a patch panel compared to some alternative implementations. Additionally, locating a sliding patch panel in an easily reached location can improve an ergonomic efficiency of reconfiguring a connection topology, in some instances reducing a risk of injury or strain (e.g., lower back strain due to bending, etc.) compared to some alternative implementations. Additionally, in some instances, sliding patch panels that are accessible from a cold aisle of a data center can in some instances reduce a need for cooling breaks or water breaks compared to some alternative implementations, thereby facilitating faster reconfiguration of a connection topology in some instances.

With reference now to the Figures, example embodiments of the present disclosure will be discussed in further detail.

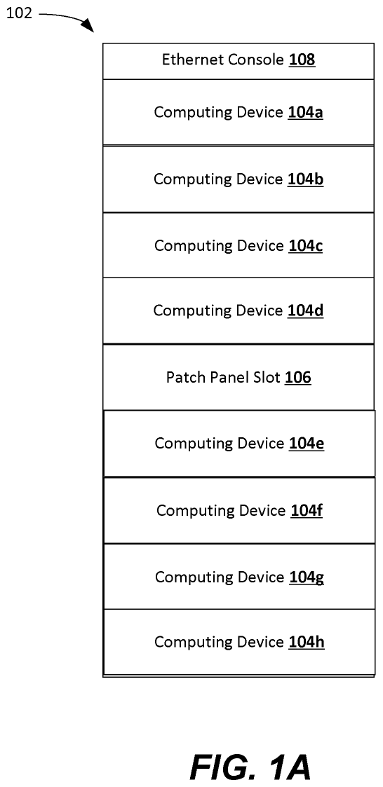

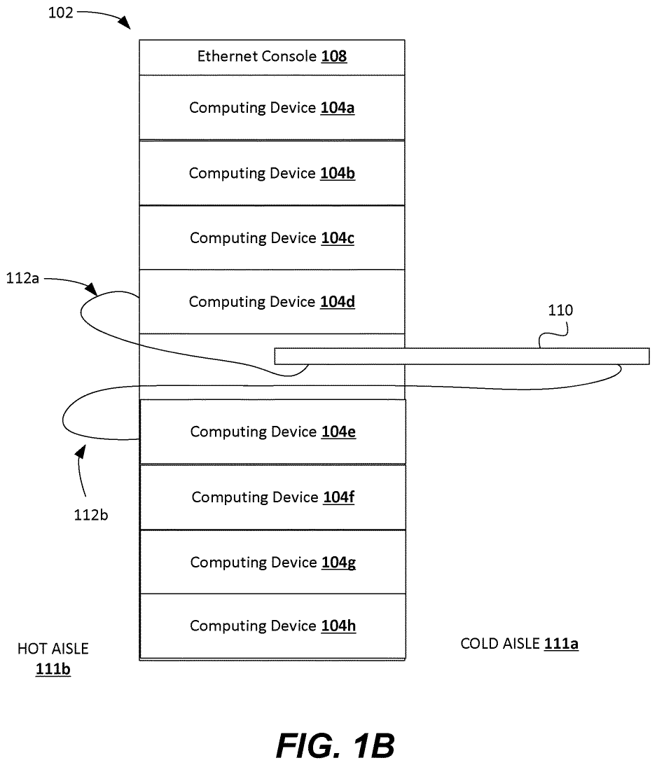

FIG. 1A depicts a first schematic diagram of an example server rack according to example implementations of aspects of the present disclosure. A server rack 102 can hold a plurality of computing devices 104. The server rack 102 can include a patch panel slot 106 configured to receive a patch panel (not depicted in FIG. 1A). In some instances, the server rack 102 can further include or be configured to receive one or more other components, such as an ethernet console 108 or the like.

A server rack 102 can be or include one or more structures for supporting, housing, or otherwise organizing electronic equipment. For example, a server rack 102 can include a frame (e.g., a 19-inch frame, a 23-inch frame, etc.) or cabinet configured to mount various components (e.g., computing devices 104, patch panel slot 106, etc.). In some instances, server rack 102 can define a plurality of mounting locations, such as slots or bays, which may be sized according to standardized units (e.g., 1U, 2U, 3U, 4U, etc.) or nonstandard units.

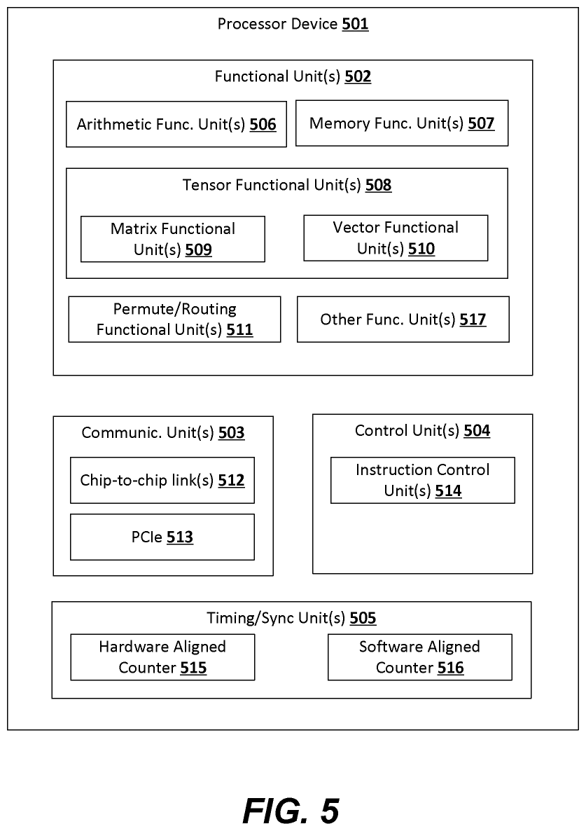

A computing device 104 can be or include one or more electronic devices configured to process, store, or transmit data. For example, a computing device 104 can include a compute node, server, or other device. In some instances, a computing device 104 can include one or more processor devices (e.g., application-specific integrated circuits, graphics processing units (GPUs), field programmable gate arrays, processor devices having one or more properties described below with respect to FIG. 5 and processors 501, etc.), such as processor devices configured to perform machine learning operations (e.g., inference operations, etc.). In some instances, a computing device 104 can be positioned within a server rack 102 and can be configured to intake cooling air from a first aisle (e.g., a cold aisle) and exhaust heated air into a second aisle (e.g., a hot aisle).

In some instances, a computing device 104 can include a plurality of communication ports for establishing network connections. In some instances, ports can include electrical ports, optical ports, or both. In some instances, ports of a computing device 104 can be configured to receive various connector types, such as fiber optic connectors. In some instances, a computing device 104 can include a high-radix configuration with a large number of ports dedicated to device-to-device communication, such as 4, 8, 16, 32, or another number. In some instances, a first portion of ports of a computing device 104 can be designated for within-rack communication—facilitating high-speed data transfer between devices in the same server rack 102—while a second portion can be designated for between-rack communication, facilitating data transfer to devices located in different racks or different regions of a data center.

In some instances, one or more communication ports of a computing device 104 can be operatively connected to a routing device (e.g., patch panel such as sliding patch panel, etc.) to facilitate flexible network topology reconfiguration, or to another destination (e.g., direct connection from a first computing device 104a to a second computing device 104b within the same rack, etc.). Further details of an example system comprising computing devices 104 connected to a sliding patch panel are provided below with respect to FIG. 1B.

The patch panel slot 106 can be or include one or more receiving structures, apertures, or bays configured to house or otherwise interface with a patch panel (e.g., sliding patch panel 110 as described below with respect to FIG. 1B, etc.) or other modular component. In some instances, the patch panel slot 106 can be an integrated part of a server rack 102, or can include a discrete device, such as a chassis or frame hardware, that mounts onto or within a server rack 102. The patch panel slot 106 can be sized according to various form factors, such as a standardized 1U, 2U, 3U, or 4U server slot.

The patch panel slot 106 can include or be associated with various mechanical components to facilitate the insertion and extraction of equipment. For instance, the patch panel slot 106 can include or be operatively connected to slide hardware, such as drawer slides, track slides, telescopic rails, or roller hardware (e.g., wheels). These components can allow a sliding patch panel to actuate between a stowed position within the footprint of the server rack 102 and an extended position outside the footprint of the server rack 102. In some instances, the patch panel slot 106 can be configured to support over-travel, allowing the contents of the slot to be fully extended to provide unobstructed access to one or more ports of a patch panel.

In some instances, the patch panel slot 106 can be located at a height configured for ergonomic or convenient access, such as between one and five feet from the ground, such as between two and four feet from the ground, such as between 2.5 and 3.5 feet from the ground.

An ethernet console 108 can include, for example, one or more networking devices (e.g., top-of-rack networking devices, etc.) configured to provide various kinds of networking operations for one or more computing devices 104a-h. In some instances, an ethernet console 108 can include one or more communication ports connected, directly or indirectly, to one or more computing devices 104a-h on the same rack in which the ethernet console 108 is located; one or more communication ports connected, directly or indirectly, to one or more devices (e.g., computing devices 104; networking devices such as other ethernet consoles 108; management devices such as control nodes or administrator devices; etc.) that may be located away from a rack in which the ethernet console 108 is located. An indirect connection can include, for example, a connection via a patch panel (e.g., sliding patch panel 110 as described below with respect to FIG. 1B, etc.) or other networking device.

FIG. 1B depicts a second schematic diagram of an example server rack according to example implementations of aspects of the present disclosure. A patch panel 110 can slide in and out of a patch panel slot 106 of a server rack 102. In some instances, the patch panel 110 can slide out into a cold-aisle 111a of the server rack 102. A plurality of computing devices 104 can be connected to a plurality of ports (e.g., bottom-side ports) of the patch panel 110 via a plurality of cables 112 (e.g., fiber optic cables, etc.).

Although FIG. 1B expressly depicts only two cables 112a, 112b for reasons of visual clarity, a larger (e.g., much larger, etc.) number of cables can be used. For example, in some instances, an example computing system can include a plurality of computing devices 104, each with a plurality (e.g., 4, 8, 16, 32, etc.) of ports designated for device-to-device communication. In some instances, some or all of the device-to-device communication ports of computing devices 104 of the server rack 102 can be operatively connected to a corresponding port (e.g., bottom-side port, etc.) of a patch panel. As a non-limiting illustrative example, in some instances, a portion of each computing device's communication ports can be designated for within-rack device-to-device communication, and a portion can be designated for between-rack device-to-device communication. Continuing the example, in some instances, each of at least the within-rack device-to-device communication ports can be operatively connected to the patch panel.

In some instances, a patch panel 110 can be or include one or more components for managing, routing, or otherwise facilitating connections between electronic devices. For example, in some instances, a patch panel 110 can include a sliding patch panel assembly configured to translate between a stowed position within a rack or enclosure and an extended position for access. In some instances, a patch panel 110 can include a chassis having a low-profile form factor, such as a “pizza box” shape, which may be dimensioned to fit within a standardized slot (e.g., a 1U, 2U, or 3U horizontal slot). In some instances, a patch panel 110 can include or be operatively connected to slide hardware, such as drawer slides, telescopic rails, or roller hardware, which can be integrated into the patch panel 110 itself or provided as part of a receiving slot or frame.

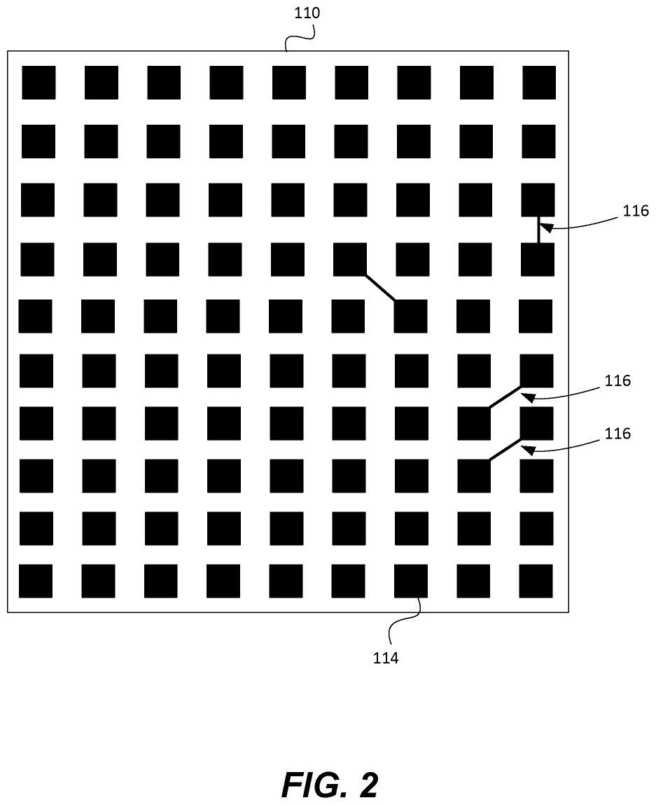

In some instances, a patch panel 110 can include a plurality of ports for establishing data links. For instance, in some instances, a patch panel 110 can include a plurality of first ports and a plurality of second ports. In some instances, at least one second port can be operatively connected to at least one corresponding first port. For example, in some instances, each respective second port can be operatively connected to at least one (e.g., exactly one, etc.) corresponding first port, such as via internal cabling or optical wave guides located within the patch panel 110. For example, in some instances, computing devices can be semi-permanently connected to the second ports of the patch panel 110, and a user or administrator can reconfigure the overall network map by connecting or disconnecting various first ports 114 (e.g., using patch cables or pre-built link panels, etc.). Further details of an example patch panel comprising a plurality of first ports and a plurality of second ports are provided below with respect to FIG. 2.

A cold aisle 111a can include, for example, one or more regions or environments within a data center having an average temperature lower than an average temperature of a hot aisle 111b, such as an aisle or corridor toward which one or more air intake components of one or more computing devices 104 are facing; an aisle or corridor away from which one or more exhaust components of one or more computing devices 104 are facing; or the like. Similarly, a hot aisle 111b can include, for example, one or more regions or environments within a data center that having an average temperature higher than an average temperature of the cold aisle 111a, such as an aisle or corridor toward which one or more exhaust components (e.g., exhaust components of a cooling system configured to draw heat away from one or more processor devices, etc.) of one or more computing devices 104a-h.

A cable 112a, b can be or include one or more transmission media for transporting data between components of a computing system, such as a fiber optic cable, copper wire, or other communication cable type.

FIG. 2 depicts a top view of an example patch panel according to example implementations of aspects of the present disclosure. The patch panel 110 can include a plurality of first ports 114 (e.g., top-side ports of a horizontally oriented patch panel 110, etc.) and a plurality of second ports (e.g., bottom-side ports not depicted in FIG. 2; bottom-side second port connected to third port associated with a computing device 104 as depicted in FIG. 1B; etc.). Each first port 114 can be operatively connected to a corresponding second port (e.g., second port directly below the first port in the top-down view of FIG. 2, etc.), such that a device or connector connected to a first port 114 is thereby connected to the corresponding second port associated with the first port 114. In some instances, a computing system can include a plurality of reconfigurable cables 116 connecting pairs of first ports 114, thereby connecting pairs of computing devices 104 that are connected to the corresponding second ports associated with the pairs of first ports 114. In some instances, reconfiguring a connection topology of a computing system can include reconfiguring the cables 116 connected to the first ports 114 of the patch panel (e.g., disconnecting some pairs of first ports 114; connecting other pairs of first ports 114; etc.).

A first port 114 can be or include, for example, one or more interfaces for establishing a communication link. In some instances, the first port 114 can be a top-side port located on the upper surface of a horizontally oriented sliding patch panel 110. In some instances, a first port 114 can be configured to receive any variety of connectors, such as electrical connectors or optical connectors. For example, in some instances, one or more first ports 114 can be first optical ports configured to receive a fiber optic connector, such as a Lucent Connector (LC), a Standard Connector (SC), or a multi-fiber push-on (MPO) connector. In some instances, each first port 114 can be operatively connected (e.g., via internal cabling or optical wave guides located within the patch panel 110) to a corresponding second port (e.g., second port located on a different side of the patch panel 110, such as a bottom side, etc.) of a plurality of second ports (e.g., second optical ports, etc.) of the patch panel 110, such that a signal entering the first port 114 is routed directly to the corresponding second port.

A cable 116 can be or include one or more transmission media for transporting data between components of a computing system, such as a fiber optic cable, copper wire, or other communication cable type. In some instances, a length of a cable 116 can be significantly smaller than a length of one or more cables 112a, b, such as smaller than a width of the patch panel 110, such as smaller than ten times a distance between a pair of first ports 114 separated by the cable 116 (e.g., smaller than five times, such as smaller than two times, etc.). In some instances, a plurality of cables 116 can include a plurality of cables that are the same length or different lengths.

In some instances, a one or more patch panels 110 can facilitate the reconfiguration of a network connection topology by providing a modular interface for changing links. For example, in some instances, computing devices can be semi-permanently connected to the second ports of the patch panel 110, and a user or administrator can reconfigure the overall network map by connecting or disconnecting various first ports 114 using patch cables or pre-built link panels. In some instances, the first ports 114 can be located on a top side of a horizontally oriented sliding patch panel 110, thereby providing faster, more ergonomic access and reduced vertical footprint compared to some alternative implementations (e.g., vertically oriented, fixed panels on a hot-aisle side of a rack, etc.). In some instances, a patch panel 110 can include first port(s) 114 located on a first side (e.g., top side, upward-facing side, etc.) of the patch panel 110 and corresponding second ports on a second side (e.g., bottom side, downward-facing side, etc.) of the patch panel 110, each first port 114 operatively connected to a second port on the second side.

In some instances, a user or administrator can reconfigure a network topology by connecting or disconnecting pairs of first ports 114 of a patch panel 110, thereby connecting or disconnecting pairs of destination ports or devices (e.g., computing devices 104a-h or ports thereof, etc.) that are connected to the first ports 114. In some instances, connecting or disconnecting pairs of first ports 114 can include by-hand connection or disconnection using individual patch cables; multi-port connection or disconnection using pre-built link panels; or another operation. A prebuilt link panel can include, for example, one or more modular assemblies for implementing a predetermined connection topology. For example, a prebuilt link panel can include a rigid or semi-rigid substrate supporting a plurality of links (e.g., fiber optic cables, copper traces, etc.) arranged in a predefined connection pattern associated with a predefined network topology. In some instances, the prebuilt link panel can be configured for quick-connect operation, such that a plurality of network connections can be established or terminated in a single motion. This can be achieved, for example, using a unified mechanical interface, such as an array of connectors that engage with the first ports 114 of the patch panel 110 simultaneously. For example, in some instances, a face of the prebuilt link panel can include a plurality of connectors that match a layout of some or all of the first ports 114, and the prebuilt link panel can include communication channels (e.g., optical channels, etc.) connecting pairs of the plurality of connectors. In some instances, a data center can maintain a library of different prebuilt link panels, each implementing a different network topology (e.g., network topologies optimized for different workloads such as a first panel for machine learning training and a second panel for distributed database operations, first panel for inference with a first machine-learned model and second panel for inference with a second machine-learned model, etc.). In some instances, reconfiguring a topology of such a computing system can include sliding out a patch panel 110, removing a first prebuilt link panel, and inserting a second prebuilt link panel (e.g., in a single quick-connect actuation). Other implementations (e.g., implementations using by-hand connection of single optical cables, etc.) are possible without deviating from the scope of the present disclosure.

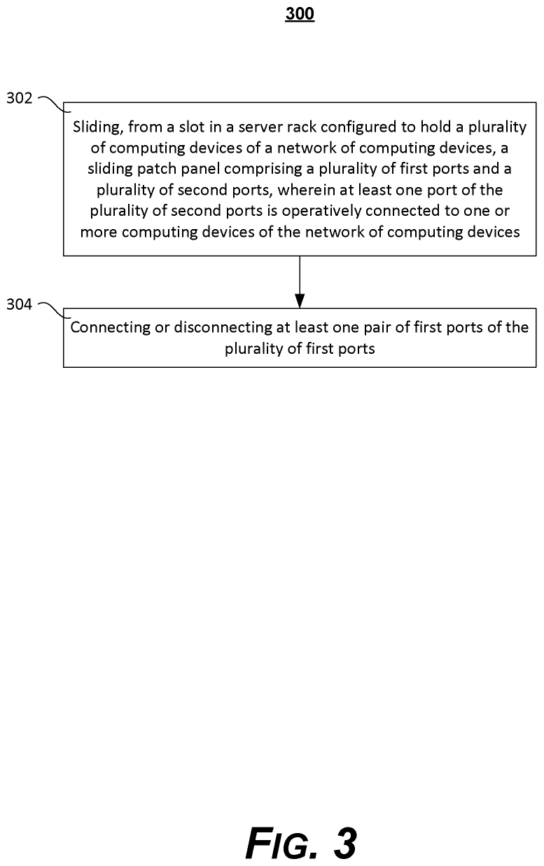

FIG. 3 depicts a flowchart diagram of an example method for reconfiguring a network topology of a network of computing devices according to example embodiments of the present disclosure. Although FIG. 3 depicts steps performed in a particular order for purposes of illustration and discussion, the methods of the present disclosure are not limited to the particularly illustrated order or arrangement. The various steps of example method 300 can be omitted, rearranged, combined, and/or adapted in various ways without deviating from the scope of the present disclosure.

At 302, example method 300 can include sliding, from a slot (e.g., patch panel slot 106, etc.) in a server rack (e.g., rack 102, etc.) configured to hold a plurality of computing devices (e.g., computing devices 104a-h, etc.) of a network of computing devices, a sliding patch panel (e.g., patch panel 110, etc.) comprising a plurality of first ports (e.g., first ports 114, etc.) and a plurality of second ports, wherein at least one port of the plurality of second ports (e.g., each port of the plurality of second ports, etc.) is operatively connected to one or more computing devices of the network of computing devices. In some instances, example method 300 at 302 can include using one or more systems or performing one or more activities described with respect to FIGS. 1A-2.

At 304, example method 300 can include connecting or disconnecting at least one pair of first ports of the plurality of first ports. In some instances, example method 300 at 304 can include using one or more systems or performing one or more activities described with respect to FIGS. 1A-2.

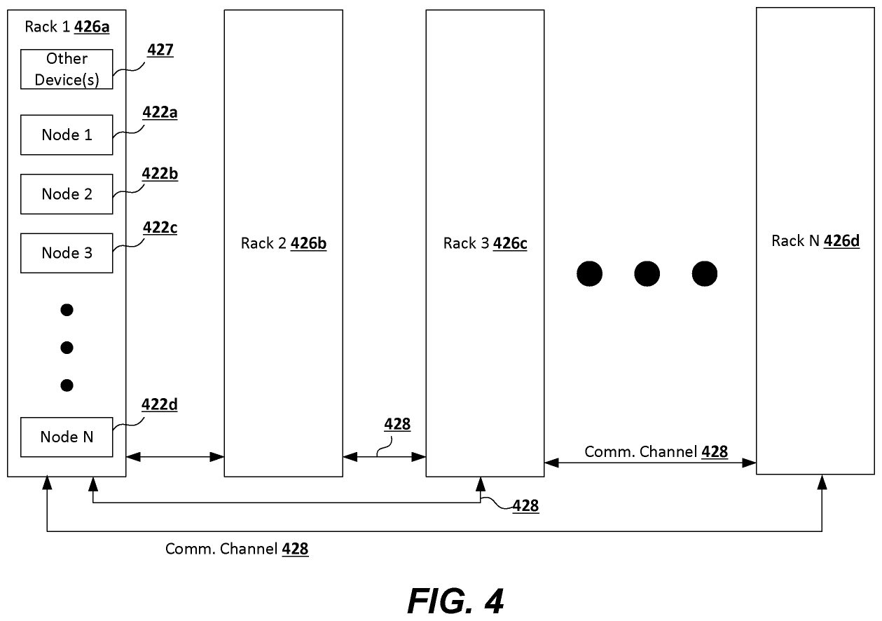

FIG. 4 is a block diagram of an example multi-rack computing system according to example implementations of aspects of the present disclosure. A computing system can include, for example, a plurality of racks 426a, b, c, d, with each rack holding a plurality of computing nodes 422 (e.g., computing nodes 422a, b, c, d, etc.) and one or more other devices 427, such as top-of-rack device(s) 427 or the like. The computing system can further include a plurality of communication channels 428, each communication channel 428 connecting one or more nodes of a first rack 426 to one or more nodes of a second rack 426.

In some instances, one or more server racks of the plurality of server racks 426 can include a patch panel slot 106 holding a sliding patch panel 110. In some instances, pairs of server racks 426 can be connected via direct device-to-device connections (e.g., via cables that do not pass through a patch panel 110), or can be connected via one or more patch panels 110. For example, in some instances, a communication channel 428 connecting a first rack 426a to a second rack 426b can include a communication channel 428 from a compute node 422 of the first rack 426a to a computing device 104 of the second rack 426b; from a compute node 422 of the first rack 426a to a patch panel 110 of the second rack 426b; or from a patch panel 110 of the first rack 426a to a patch panel 110 of the second rack 426b. For example, in some instances, reconfigurable between-rack connection topologies can be facilitated by connecting, using a between-rack communication channel 428, a second port (e.g., bottom-side port, etc.) of a first patch panel 110 of a first rack 426a to a second port (e.g., bottom-side port, etc.) of a second patch panel 110 of a second rack 426b. Reconfiguring the between-rack connection topologies can include connecting or disconnecting a compute node 422 (or first port 114 associated with a compute node 422, etc.) to or from a first port 114 that is connected to the between-rack communication channel 428. Other examples are possible.

A rack 426 can include, for example, a structure (e.g., server rack, cabinet, etc.) configured to contain a plurality of compute nodes 422. In some instances, a rack 426 can include a standard-sized rack for holding server computing devices, and each of a plurality of compute nodes 422 can include a standard-size compute node for being inserted into a server rack, such as a one-rack-unit (1U), 2U, or 4U node, or other standard compute node size.

Other device(s) 427 can include, for example, one or more shared devices configured to provide one or more functions to a plurality of compute nodes 422. In some instances, other device(s) 427 can include one or more communication devices, such as top-of-rack communication devices. Top-of-rack communication devices can include, for example, a top-of-rack switch; patch panel; routing panel; retimer; or other communication device.

Communication channels 428 can include various kinds of communication channels, such as electrical communication channels (e.g., conductive wiring such as copper, etc.), optical communication channels (e.g., fiber optic strands, cables, etc.), or other communication channel type. In some instances, communication channels 428 can include communication channels 428 between top-of-rack communication devices 427 (e.g., Ethernet communication channels, etc.); direct chip-to-chip communication channels 428 between a first processor device (e.g., processor device 501 as described below with respect to FIG. 5, etc.) of a first rack 426 and a second processor device of a second rack; direct node-to-node communication of a first shared communication device of a first node of a first rack 426 and a second shared communication device of a second node of a second rack 426; or other communication channel. In some instances, a plurality of communication channels 428 can form various kinds of communication topologies, such as high-radix topologies wherein each of a plurality of processor devices of a plurality of racks 426 has multiple chip-to-chip communication ports (e.g., greater than or equal to eight, etc.). In some instances, a topology of the communication channels 428 can include one or more reconfigurable topologies, such as topologies wherein some or all of a plurality of chip-to-chip communication units are each connected to one or more topology reconfiguration devices, such as one or more switches; patch panels; connectorized fixed-topology routing panels configured to route a plurality of inputs (e.g., plurality of inputs associated with a multi-strand fiber optic connector, etc.) to a plurality of outputs according to a predetermined topology, thereby enabling rapid switching between topologies by disconnecting from a first fixed-topology routing panel and connecting to a second fixed-topology routing panel.

In some instances, communication channels 428 can include or be coupled to various communication components, such as communication ports, connections, interface units, or the like; routing or data permutation components (e.g., internal routing or permutation components such as switching components; external components coupled to a processor device such as routers, repeaters, switches, panels, or the like); communication lines (e.g., electrically conductive signal traces, electrically conductive wires, optical fibers, cables, etc.); or other components configured to facilitate one or more communication operations.

FIG. 5 is a block diagram of an example processor device 501 according to example implementations of aspects of the present disclosure. The processor device 501 can include one or more functional units 502; one or more communication units 503; one or more control units 504 (e.g., instruction control unit(s) 514, etc.); one or more timing or synchronization units 505; or other components. In some instances, functional unit(s) 502 of the processor device 501 can include one or more of: arithmetic functional unit(s) 506; memory functional unit(s) 507; tensor functional unit(s) 508 (e.g., matrix functional unit(s) 509, vector functional unit(s) 510, etc.); permute or routing functional units 511; or other functional units 517. Communication unit(s) 503 can include, for example, one or more of chip-to-chip communication link(s) 512, peripheral component interconnect express 513 components, or other communication unit(s) 503. Timing and synchronization units 505 can include, for example, one or more hardware-aligned counters 515, one or more software-aligned counters 516, or other timing or synchronization components.

The processor device of FIG. 5 is provided by way of example only, and other devices or architectures can be used without deviating from the scope of the present disclosure. For example, in some instances, patch panels according to aspects of the present disclosure can be used to provide reconfigurable connections between various kinds of devices capable of transmitting or receiving communication signals over a communication channels, such as computing device(s); communication device(s); control device(s); sensor device(s); or other device type. As another example, in some instances, patch panels according to aspects of the present disclosure can be used to provide reconfigurable connections between two or more devices of the same type; between devices of two or more different types (e.g., between a computing device and a routing device; between two computing devices having different processor architectures; etc.); or both.

A processor device 501 can include various types of processor architectures. In some instances, a processor device 501 can include a single-core or multi-core processor device 501. In some instances, a processor device 501 can include an integrated circuit located on a single die or a processor device 501 distributed over multiple dies connected together (e.g., directly connected such as via face-to-face connection, indirectly connected such as via one or more interposers, etc.). In some instances, a processor device 501 can include one or more of: one or more field-programmable gate arrays (FPGAs); one or more application-specific integrated circuits (ASICs), such as ASICs for machine-learning inference, matrix multiplication, floating-point operations, or the like; one or more graphics processor units (GPUs); one or more tensor processing devices; or other processor type. In some instances, a processor device 501 can include a deterministic processor device or a non-deterministic processor device (e.g., processor device configured to operate according to a deterministic or non-deterministic timing, etc.). In some instances, a processor device 501 can include a processor device having a plurality of dedicated special-purpose functional units, or a processor device having one or more general-purpose functional units (e.g., multi-core processor having a plurality of general-purpose processor cores, etc.). For example, in some instances, a processor device 501 can include a single-core processor device 501 having a plurality of special-purpose functional units 502 having distinct functions, such as functional units 502 having distinct instruction set architectures.

In some instances, a processor device 501 can include a deterministic processor device. A deterministic processor device can include, for example, a processor device configured to perform a plurality of operations according to a predetermined order, such as a predetermined program order defined by a compiler. In some instances, a deterministic processor device can include a processor device configured to perform a plurality of operations according to a predetermined timing or according to a predetermined temporal relationship between operations. For example, in some instances, a deterministic processor can include a processor configured to receive one or more computer-executable instructions (e.g., compiled instructions, etc.) comprising timing data; and execute the instruction(s) according to a predetermined time or predetermined temporal relationship indicated by the timing data. Timing data can include, for example, one or more of: data indicative of a clock cycle on which to execute a particular operation; data indicative of a temporal relationship between one or more first operations and one or more second operations, such as data indicative of a number of clock cycles to pause after a first operation (e.g., data transfer operation, instruction transfer operation, floating-point operation, etc.) is completed before performing a second operation (e.g., floating-point operation, tensor processing operation, etc.); data indicative of one or more operations or instructions configured to have an effect on a timing of operations, such as data indicative of one or more no-operation (NOP) operations or sleep operations, such as a repeated-NOP instruction to cause a functional unit 502 or other component of a processor device 501 to remain idle for a predetermined number of clock cycles; or other timing data.

In some instances, a deterministic processor device can include a processor device configured to receive, from a compiler, a set of computer-executable instructions controlling a timing of a plurality of operations associated with the computer-executable instructions; and perform the plurality of operations according to the timing. For example, in some instances, a deterministic processor device can include a processor device configured to receive a compiled program configured to cause, for each respective operation of a plurality of operations (e.g., arithmetic operations such as floating-point operations, tensor operations, etc.) to be performed on one or more respective data operands (e.g., numerical operands such as machine-learning model parameters, activation values, etc.), an instruction associated with the respective operation to intersect with the respective data operand at a predetermined time instant (e.g., clock cycle, clock cycle offset relative to an initial clock cycle, etc.) defined in the compiled program. In some instances, a deterministic processor can include a processor device having one or more components (e.g., functional unit(s) 502, communication unit(s) 503, etc.) having an instruction set architecture comprising instructions to control a timing of one or more operations of the one or more components.

In some instances, a deterministic processor device 501 can include a processor device configured to route data between functional units 502 of the processor device 501 according to a predetermined timing, predetermined routing or pathing, or both. For example, in some instances, a deterministic processor device 501 can include a processor device configured to receive compiled instructions comprising data indicative of one or more data transfer operations to be performed according to one or more predetermined routes determined by a compiler, according to one or more predetermined timing values defined by the compiler, or both. In this manner, for instance, a deterministic processor device 501 can enable a compiler to perform compile-time load balancing for a plurality of data paths, and can execute a plurality of runtime data transfers according to the compile-time load balancing.

In some instances, a deterministic processor device 501 can include a processor that lacks one or more non-deterministic components that may be commonplace among non-deterministic processor devices, such as branch prediction units, tiered or hierarchical cache devices, runtime load balancing, or other sources of runtime non-determinism (e.g., non-deterministic timing of operations, non-deterministic choice of operations such as non-deterministic routing of data, etc.). For example, in some instances, a processor device 501 can lack any branch prediction components, and can be configured to execute every operation of a compiled program according to a predetermined program order. As another example, in some instances, one or more memory functional units 507 can lack a cache hierarchy or lack any non-deterministic memory component(s). For example, in some instances, one or more memory functional units 507 can be configured to operate deterministically, such as according to a predetermined timing defined by a compiler. For example, in some instances, one or more memory functional units 507 can be configured to perform one or more read operations at one or more times predetermined by a compiler; perform one or more write operations at one or more times predetermined by the compiler; perform one or more refresh operations at one or more times predetermined by the compiler, such that the compiler can have explicit control over a refresh timing of the memory functional unit(s) 507; or the like. For example, in some instances, the compiler can compile a program or other executable into a set of deterministic operations that can be executed by the functional unit(s) 502 at known times specified by a deterministic schedule.

However, although a deterministic processor device 501 can lack some common sources of non-determinism, in some instances, a deterministic processor device 501 can include or interact with one or more non-deterministic components or devices without deviating from the scope of the present disclosure. As a non-limiting illustrative example, in some instances, a deterministic processor device 501 can include a PCIe 513 component configured to perform external input/output (I/O) operations, which can in some instances include input/output operations having a non-deterministic timing (e.g., I/O operations using a non-deterministic PCIe 513 device; I/O operations receiving input from non-deterministic external device(s); etc.). In some instances, a deterministic processor device 501 can interact with non-deterministic component(s) or device(s) (e.g. components or devices internal or external to the processor, etc.), while maintaining deterministic operation of the remaining components of the processor device 501 by designating one or more predetermined time windows to interact with the non-deterministic component(s) in a deterministic manner. For example, in some instances, a processor device 501 can be configured to check, at each of a plurality of predetermined times, whether one or more inputs (e.g., inference request(s), etc.) has been received via a PCIe device 513; and, if the processor device 501 determines that an input has been received, to process the input (e.g., write the input to a designated memory location or region, etc.) according to a predetermined timing or predetermined set of instructions (e.g., according to a set of operations configured to fit within a predetermined time window reserved for non-deterministic external I/O operations, etc.).

In some instances, a processor device 501 can include a processor device configured for single-instruction multiple-data (SIMD) operation. For example, in some instances, a processor device 501 can be configured to receive one or more computer-executable instructions that are each indicative of an operation to be performed on a plurality of operands, such as a vector of numerical operands; a tensor of numerical operands; or the like. In some instances, a SIMD processor device can include a processor device configured to provide a single instruction to a plurality of functional units 502 (e.g., adjacent functional units 502 arranged in a functional region, etc.) to cause each respective functional unit 502 of the plurality of functional units 502 to execute the instruction on one or more distinct operands provided to the respective functional unit 502 (e.g., routed to the respective functional unit 502 according to a predetermined compiler-defined routing, etc.).

In some instances, a processor device 501 can include a single-core processor device, or a processor device configured to operate as a single-core device (e.g., flexible-operation processor device having two hemispheres that can be operated in series as a single-core device or in parallel as a multi-core device, etc.). For example, in some instances, a single-core processor device can include a processor device configured to receive a single set of instructions (e.g., compiled instructions, etc.) and to execute, in a serial or pipelined fashion using one or more functional units 502, a set of operations defined by the single set of instructions. For example, in some instances, a single-core processor device 501 can include a processor device configured to obtain (e.g., receive, retrieve, etc.) one or more instructions (e.g., SIMD instructions, etc.) indicative of a plurality of operations (e.g., plurality of SIMD operations, etc.) to be performed on one or more operands; and perform, in series using a plurality of functional units 502, the plurality of operations (e.g., SIMD operations wherein each operation is a multiple-data operation, etc.) on the one or more operands.

Functional unit(s) 502 can include, for example, one or more components (e.g., integrated circuit components, etc.) configured to perform operations on one or more operands (e.g., data operands, etc.). In some instances, functional unit(s) 502 can include deterministic functional units 502, such as deterministic functional units configured to perform one or more operations in a predetermined program order, according to a predetermined timing or temporal relationship, or the like. In some instances, a set of functional units 502 can include a plurality of dedicated or special-purpose functional units 502, such as distinct functional units 502 having distinct functions or sets of functions (e.g., limited or specialized function sets, etc.). In some instances, functional unit(s) 502 can include functional units configured to perform multiple operations per instruction for at least some instructions, such as single-instruction multiple-data (SIMD) functional unit(s) 502, and/or functional unit(s) 502 configured to process instruction(s) directed to multiple computing operations (e.g., multiple repetitions of a single type of operation, pipeline of multiple different operations, etc.).

In some instances, a set of dedicated functional unit(s) 502 can include distinct dedicated functional units 502 for each of a plurality of steps in a machine-learning inference pipeline, such as a distinct dedicated functional unit for each component of a category or type of machine-learning model layer (e.g., convolutional layer, attention layer, fully connected layer, etc.). For example, in some instances, a set of dedicated functional units 502 for implementing a fully connected layer of a machine-learning model can include one or more matrix functional units 509 for performing matrix multiplication between a parameter tensor (e.g., weight matrix, etc.) and a tensor (e.g., vector, etc.) of input values to the fully connected layer, and one or more vector functional units 510 for performing an activation function of the fully connected layer. As another example, in some instances, a set of dedicated functional units 502 for implementing a convolutional layer of a machine-learning model can include one or more permute/routing functional units 511 configured to perform one or more data reshaping operations corresponding to one or more convolutions (e.g., two-dimensional convolutions, one-dimensional convolutions, etc.); and one or more other functional units 502 (e.g., matrix functional unit(s) 509, vector functional unit(s) 510, etc.) for performing additional operations associated with a convolutional layer or convolutional neural network (e.g., matrix multiplication, pooling, activation functions, etc.).

In some instances, a plurality of dedicated functional units 502 can include a first functional unit 502 configured to perform a set of operations that is different (e.g., completely disjoint from or partially overlapping, etc.) from a second set of operations associated with a second functional unit 502. In some instances, a plurality of special-purpose or dedicated functional units 502 can have a plurality of distinct instruction set architectures, such as limited or special-purpose instruction set architectures each supporting a limited or special-purpose set of operations. As a non-limiting illustrative example, in some instances, a set of dedicated functional units 502 can include one or more of: a matrix functional unit 509 configured to perform a first set of matrix operations (e.g., matrix multiplication operations, etc.); a vector functional unit 510 configured to perform a set of vector operations different from the matrix operations (e.g., activation function operations such as rectified linear unit (ReLU), sigmoidal, softmax, or other activation function operations; normalization operations; etc.); a permute/routing functional unit 511 configured to perform one or more data routing, data permutation, or data reshaping functions (e.g., tensor permutation or reshaping, etc.) different from the matrix operation(s) and different from the vector operation(s); or other dedicated functional unit(s) 502. Other examples are possible.

In some instances, functional unit(s) 502 can include functional units organized into functional regions of a processor die, such as compact functional regions configured to facilitate low-latency propagation of instructions or operands within a functional unit 502 or between adjacent functional units 502. As a non-limiting illustrative example, in some instances, one or more functional units 502 can be organized into functional slices along a first axis of a processor die, thereby enabling low-latency propagation of one or more instructions along the axis, low-latency propagation of operand data along a second axis, or the like.

In some instances, functional unit(s) 502 or functional region(s) can be geographically organized on a processor die to reduce (e.g., minimize or nearly minimize; reduce relative to a random arrangement or relative to a conventional multi-core central processing unit or conventional graphics processing unit, etc.) a communication cost (e.g., latency cost, power cost, communication distance, etc.) associated with one or more computational pipelines, such as machine-learning inference pipelines. For example, in some instances, one or more functional units 502 or functional regions of a processor device 501 for performing a sequentially first operation in a computational pipeline can be geographically close to one or more functional units 502 for performing a sequentially second operation in the computational pipeline. Example computational pipelines can include, for example, inference pipelines associated with common machine-learning model, layer, or head architectures, such as convolutional architectures; attention architectures; fully connected layer architectures; selective structured state space machine architectures; gating architectures (e.g., long short-term memory, etc.); or another machine-learning architecture.

In some instances, functional unit(s) 502 can include functional units configured to perform multiple operations per instruction for at least some instructions, such as single-instruction multiple-data (SIMD) functional unit(s) 502 or functional units 502 configured to operate without necessarily receiving explicit instructions for each operation. For example, functional unit(s) 502 configured to operate without necessarily receiving explicit instructions for each operation can include one or more of: functional unit(s) 502 configured to receive intermittent instructions and perform multiple operations per instruction (e.g., repeated single operation, pipeline of multiple different operations, etc.); functional unit(s) 502 configured to operate without instructions according to a default operation; or the like. In this manner, for instance, an amount of communication required to provide instructions to the functional units 502 can be reduced, and operation of the processor device 501 can in some instances be simplified compared to some alternative implementations.

For example, in some instances, a SIMD functional unit 502 can include a tensor functional unit 508 configured to execute an instruction on a plurality of numerical values, such as a vector or matrix of numerical values. For example, in some instances, a tensor functional unit 508 can be configured to receive an instruction; and process, according to the instruction, a tensor (e.g., one-dimensional vector tensor, two-dimensional matrix tensor, etc.) comprising a plurality of numerical values (e.g., dozens of numerical values per instruction, such as hundreds, such as 320 numerical values in some examples). In some instances, a tensor functional unit 508 can be configured to process some or all of a plurality of values simultaneously, or to execute a single-instruction multiple-data instruction according to a staggered timing.

As another example, in some instances, a functional unit 502 configured to operate based on intermittent instructions can include a functional unit 502 configured to repeat one or more operations, such as a functional unit 502 configured to continue performing a given operation (e.g., an operation associated with a most recently received instruction, etc.) periodically (e.g., at every clock cycle; at every Nth clock cycle; etc.) for some amount of time (e.g., indefinitely, for a finite period of time such as a time period defined by a previously received instruction, etc.) in the absence of explicit instructions. In some instances, a functional unit 502 can include a functional unit 502 configured to receive and execute one or more repetition instructions (e.g., having an instruction set architecture comprising one or more repetition instructions, etc.). A repetition instruction can include, for example, an instruction to cause the functional unit 502 to repeat (e.g., repeat at every clock cycle; at every Nth clock cycle, where N can be a parameter of the instruction; etc.) a previous instruction or set of instructions a number of times specified by the instruction; an instruction indicative of an operation to be repeated (e.g., arithmetic operation, matrix operation, vector operation, etc.), the instruction having a repetition parameter indicating a number of times to repeat the operation; or the like. In some instances, a repetition instruction can include one or more offset parameters, such as a time offset parameter (e.g., number of cycles to wait between repetitions, etc.), location offset parameter indicative of a distance between consecutive locations (e.g., functional unit 502 location, memory location, data path location, etc.) associated with a repeated operation, or other offset parameter.

As another example, in some instances, a functional unit 502 can include a functional unit 502 configured to receive a single instruction indicative of multiple distinct operations to be performed on a single operand or set of operands, such as a multiply-accumulate (MACC) instruction or matrix multiplication instruction indicative of one or more multiply operations and one or more accumulate operations to be performed on one or more outputs of the multiply operation(s). In some instances, a functional unit 502 can include a pipelined hardware architecture (e.g., systolic array pipelined hardware, deterministic streaming hardware, etc.) configured to provide (e.g., directly; indirectly via one or more buffers, registers, or other memory components; etc.) an output of one or more first hardware devices (e.g., floating-point units, etc.) for performing earlier (e.g., sequentially first, etc.) operations of a multi-operation instruction to an input of one or more second hardware devices for performing later (e.g., sequentially second or last, etc.) operations of the multi-operation instruction. In some instances, a pipelined hardware architecture of a functional unit 502 can include a geographically compact architecture, wherein a plurality of components for performing a multi-operation instruction can be adjacent or otherwise close together on a processor die.

An arithmetic functional unit 506 can include, for example, one or more functional units 502 for performing various arithmetic operations, such as floating-point operations, integer operations, or quantized operations; simple operations (e.g., add, multiply, format conversion, etc.) or complex/combined operations (e.g., multiply-accumulate, etc.); single-operand operations or multi-operand operations (e.g., tensor operations, etc.); or other arithmetic operations. In some instances, an arithmetic functional unit 506 can be a tensor functional unit 508 or component thereof, or have one or more properties described below with respect to tensor functional unit(s) 508.

A memory functional unit 507 can include, for example, one or more functional units 502 for reading, writing, or storing various kinds of data, such as operand data, instruction data, or other data. Data storage can include, for example, temporary storage of one-time-use or ephemeral values (e.g., computed operand values, etc.), longer-term storage of values to be reused (e.g., machine-learning model weights, compiled computer-executable instructions, etc.), or other storage. In some instances, a memory functional unit 507 can include one or more low-latency, high-bandwidth, or otherwise rapidly accessible memory devices, such as random access memory (RAM) devices (e.g., static random access memory (SRAM), high-bandwidth memory (HBM), dynamic random access memory (DRAM), etc.), registers, or other low-latency devices.

In some instances, one or more memory functional units 507 can be configured to share a global address space accessible to a plurality of functional units 502. For example, in some instances, a global address space can include all memory locations available to the processor device 501 (e.g., including any external memory modules, etc.), such that any functional unit 502 of the processor device 501 can obtain (e.g., receive at a predetermined time defined by the compiler, such as without requiring the functional unit 502 to output any request for the data obtained). In some instances, a set of memory functional unit(s) 507 can include, or a processor device 501 can have access to, one or more internal (e.g., on-chip) memory functional units 507; one or more external (e.g., off-chip, near-compute, etc.) memory units; or both.

A tensor processing unit 508 can include, for example, a functional unit 502 to perform one or more operations (e.g., arithmetic operations such as tensor multiplication, elementwise multiplication, normalization, activation function operations, etc.) on one or more tensors (e.g., matrices, vectors, etc.). In some instances, a tensor processing unit 508 can include a matrix functional unit 509; a vector functional unit 510; or another functional unit.

A matrix processing unit 509 can include, for example, a functional unit 502 configured to perform one or more operations on a matrix (e.g., two-dimensional matrix, flattened matrix, etc.) of operands (e.g., numerical values such as floating-point values, etc.). In some instances, a matrix processing unit 509 can include a functional unit 502 configured to perform matrix multiplication or other matrix operations.

A vector processing unit 510 can include, for example, a functional unit 502 configured to perform one or more operations on a vector (e.g., one-dimensional vector, flattened tensor, etc.) of operands (e.g., floating-point numerical values, etc.). In some instances, a vector processing unit 510 can include a functional unit 502 configured to perform one or more of: one or more activation function operations (e.g., sigmoidal or logistic activation function, linear unit activation function such as rectified linear unit (ReLU), softmax activation function, etc.), one or more normalization operations (e.g., L2 normalization, etc.), one or more combining operations (e.g., attention-based combining, etc.) to combine a set (e.g., pair, trio, etc.) of vectors, one or more constituent operations configured to be combined to support a class of related operations (e.g., class or category of normalization operations, class or category of activation function operations, etc.), or the like.

A permute/routing functional unit 511 can include, for example, a functional unit 502 configured to perform one or more data permuting or data routing operations. In some instances, a data permuting operation can include one or more swap or reordering operations configured to reorder data in an ordered format (e.g., vector format or other tensor format; ordered arrangement of registers, signal lines, or other hardware units; etc.), such as without changing a shape (e.g., length, width, number of dimensions, etc.) of the ordered format. Example reordering operations can include, for example, rotation or translation operations; arbitrary reordering operations defined by one or more reordering maps such as a gather map; or other reordering operations. In some instances, a data permuting operation can include a reshaping operation, such as a reshaping operation changing a number of dimensions of a data structure (e.g., tensor, hardware devices corresponding to a tensor, etc.), changing a size of one or more dimensions of the data structure, or the like. As a non-limiting illustrative example, in some instances, a reshaping operation can include a tensor flattening operation to convert a multi-dimensional tensor into a one-dimensional data structure (e.g., vector, hardware configuration corresponding to a vector, one-dimensional data stream corresponding to a vector, etc.). As another example, in some instances, a reshaping operation can include an expansion or duplication operation, such as a reshaping operation to generate an expanded convolutional kernel to implement a filter component of a convolutional neural network. In some instances, a routing operation can include a permuting operation to change an ordering of operands input to one or more fixed or predetermined data paths, or another routing operation (e.g., switching operation; pair of operations comprising a send and a receive; etc.). In some instances, a permuting operation can include a routing operation to change a routing of operands to hardware having a fixed or predetermined input order.

In some instances, a memory functional unit 507; a tensor, matrix, or vector functional unit 508, 509, 510; or a permute/routing functional unit 511 can be or include a deterministic functional unit 502 configured to execute instruction(s) at a predetermined time defined by a compiler; a single-instruction multiple-operation functional unit 502 configured to perform a plurality of operations based on one instruction; or have any other property described herein with respect to functional unit(s) 502.

Communication units 503 can include various components for performing communication operations (e.g., input, output, etc.) between the processor device 501 and other devices (e.g., processor devices, computing devices, external memory devices, etc.) or components, or within the processor device 501. In some instances, communication units 503 can include deterministic communication units (e.g., communication units performing operations according to a predetermined program order, timing, temporal relationship, or other predetermined property, etc.), non-deterministic communication units (e.g., communication units having non-deterministic timing properties, communication units configured to communicate with non-deterministic external devices, etc.), or both. For example, in some instances, a deterministic processor device 501 can include a plurality of deterministic chip-to-chip communication links 512 configured to communicate with other deterministic processor devices 501 (e.g., using deterministic communication operations having a predetermined timing, communication path, or other property), along with one or more PCIe components 513 configured to interact with one or more non-deterministic components. In some instances, communication units 503 can include or have access to various components, such as serializer-deserializer (SerDes) units configured to serialize data to be output or deserialize data received as input; communication ports, connections, interface units, or the like; communication lines (e.g., electrically conductive signal traces, electrically conductive wires, optical fibers, cables, etc.); routing or data permutation components (e.g., internal routing or permutation components such as switching components; external components coupled to the processor device 501 such as routers, repeaters, switches, panels, or the like); or other components configured to facilitate one or more communication operations.

Chip-to-chip communication units 512 can include, for example, any device or component for communicating with another processor device (e.g., processor device 501, etc.), such as one or more serializer-deserializer units, one or more communication channels (e.g., signal lines, etc.), one or more connection components (e.g., ports, pins, connection pads, etc.), or the like. In some instances, a processor 501 can include a plurality of chip-to-chip communication ports to facilitate direct communication with a plurality (e.g., four, eight, sixteen, etc.) of other chips, such as according to a high-radix chip-to-chip communication topology (e.g., dragonfly topology, hyperX topology, etc.), such as a topology having greater than or equal to eight chip-to-chip communication links per processor device 501. In some instances, chip-to-chip communication units 512 can include units configured to communicate with processor devices that are geographically close to or far away from the processor device 501 (e.g., in a same or different compute node as the processor device 501; in a same or different rack; etc.). In some instances, chip-to-chip communication units 512 can include connections to a plurality of distinct chips, a plurality of connections to a single chip, or both. In some instances, chip-to-chip communication units 512 can include chip-to-chip communication units 512 associated with one or more bidirectional communication channels, one or more unidirectional communication channels, or both. In some instances, chip-to-chip communication units 512 can include deterministic communication units configured to perform chip-to-chip communication operations (e.g., send operation, receive operation, etc.) at one or more times predetermined by a compiler; deterministic communication units having a known or deterministic timing for one or more data transfer operations; or the like. In some instances, one or more timing units 505 can be used to provide synchronization for one or more processor devices 501 to facilitate deterministic-timing communication between chips.

A peripheral component interconnect express (PCIe) component 513 can include, for example, a communication device configured to facilitate communication between a processor device 501 and one or more other devices (e.g., computing devices; processor devices; data storage devices; auxiliary devices; etc.). In some instances, a PCIe unit 513 can include a communication system conforming to one or more PCIe communication standards (e.g., PCIe 6.0, PCIe 7.0, etc.). Although FIG. 5 depicts a PCIe unit 513, other communication units or communication standards can be used without deviating from the scope of the present disclosure. In some instances, a processor device 501 can include a deterministic processor device 501 configured to communicate non-deterministically via the PCIe unit 513 while maintaining determinism in the functional unit(s) 502 of the processor device 501 (e.g., according to methods described above).

In some instances, control unit(s) 504 can include one or more devices for controlling one or more operations of the functional unit(s) 502, such as device(s) configured to supply one or more control signals (e.g., assembly code or machine code instructions; switching signals, multiplexer selection signals, etc.) to one or more functional unit(s) 502.

In some instances, control unit(s) 504 can include one or more instruction control unit(s) 514 configured to supply computer-executable instruction(s) to one or more functional units. In some instances, an instruction control unit 514 can include a deterministic instruction control unit 514 configured to supply instruction(s) to the functional unit(s) 502 according to a predefined program order determined by the compiler; supply instruction(s) at one or more predefined times (e.g., clock cycles, etc.); or the like. In some instances, an instruction control unit 514 can include hardware configured to fetch (e.g., prefetch, etc.) instruction(s) from memory at a first time (e.g., before the instructions are needed; during a time of off-peak memory usage; at a time predetermined by a compiler; etc.) and provide corresponding instruction(s) to one or more functional unit(s) 502 at a second time (e.g., second time predetermined by the compiler, etc.)

In some instances, instruction(s) provided to a functional unit 502 by an instruction control unit 514 can be the same as or different from a corresponding instruction received by the instruction control unit 514. For example, in some instances, an instruction control unit 514 can include a unit configured to translate one or more compiled instructions (e.g., instructions in a first computing language or format output by a compiler, etc.) to one or more control signals (e.g., instructions in a second language or format; other control signals such as multiplexer selection signals or the like). In some instances, translating compiled instructions can include translating a memory-efficient stored instruction to a plurality of control signals that may include a greater data volume than the memory-efficient stored instruction. For example, in some instances, translating compiled instructions can include retrieving, from a memory functional unit 507, a compiled instruction; and providing, based on the compiled instruction, a plurality of control signals to one or more (e.g., a plurality of) functional units 502 over one or more (e.g., a plurality of) clock cycles. In some instances, a memory-efficient stored instruction can include a multi-operation instruction associated with a plurality of related operations (e.g., operations of a machine-learning model layer such as matrix multiplication, activation functions, convolution, attention, or the like), and the translated control signals can include a plurality of control signals (e.g., lower-level instructions, etc.) for executing the multi-operation instruction. In some instances, an instruction control unit 514 can include hardware configured to receive an instruction comprising one or more timing parameters (e.g., delay amounts, etc.) or repetition parameters, and output control signal(s) to the functional unit(s) 502 to cause the functional units to perform operations according to the timing or repetition parameters (e.g., at a predetermined clock cycle defined by a compiler, etc.). In some instances, the instruction control unit 514 can control a timing or a number of repetitions of the functional unit(s) 502 by sending control signals comprising timing or repetition data, or by sending raw control signals at a specific time or plurality of times configured to cause the functional unit(s) 502 to perform operations according to one or more timing or repetition parameters.

In some instances, timing and synchronization units 505 can include various components configured to perform synchronization operations, such as operations to track or communicate time data (e.g., current clock cycle data, etc.) to one or more functional units 502 or other components of a processor device 501. In some instances, timing and synchronization units 505 can include one or more of: one or more hardware-aligned counters 515, one or more software-aligned counters 516, or other timing or synchronization component.

Hardware-aligned counters 515 may be used to establish a time base for electronic circuitry in each processor device 501, such as a clock, for example. Additionally, each processor device 501 may include software-aligned counters 516. Software-aligned counters 516 may be synchronized, for example, based on one or more computer-executable instructions (e.g., compiled instructions determined by a compiler, etc.). Hardware-aligned counters 515 and software-aligned counters 516 may be implemented as digital counter circuits, for example, on each integrated circuit (e.g., each processor device 501 or each die thereof, etc.). For instance, hardware-aligned counters 515 may be free-running digital counters (e.g., 8-bit counters) on a processor device 501 that are synchronized periodically. Similarly, software-aligned counters 516 may be digital counters (e.g., 8-bit counters) that are synchronized based on timing markers triggered by one or more compiled programs.

In some instances, timing and synchronization units 505 can include one or more components 505 for internal synchronization of a plurality of components (e.g., functional units 502, etc.) of a processor device 501; one or more components 505 for external synchronization between a first processor device 501 and one or more other devices (e.g., a plurality of second processor devices 501, etc.); or both.

In some instances, synchronizing a first device (e.g., first processor device 501 or another device) with a second device (e.g., second processor device 501 or another device, etc.) can include, for example, synchronizing one or more hardware-aligned counters 515 of the first processor device 501 with one or more hardware-aligned counters of the second device. Synchronizing the hardware-aligned counters 515 may occur periodically during the operation of each processor device 501 and may occur at a higher frequency than synchronizing software counters 516, for example. Synchronizing hardware counters may include the first device sending a timing reference (e.g., timing bits representing a time stamp) to the second device over a communication channel (e.g., via chip-to-chip communication units 512, etc.). In some instances, a first processor device 501 may send an 8-bit time stamp, for example. In such a scenario, a hardware counter 515 and software counter 516 of the first device may be maintained in sync locally. However, as the hardware counter 515 on a first device is synchronized to the hardware counter 515 on a second device, the software counter 516 on the second device may drift.

In some instances, software-aligned counters 516 of a pair of devices can be synchronized by providing, in each of the devices (e.g., as part of a compiled program executed by the devices, etc.), one or more timing markers configured to be sequentially triggered (e.g., at predetermined positions in a compiled program corresponding to particular points of time or particular cycles). In some instances, timing markers in each device may be configured to trigger on the same cycle in each processor device 501. For example, a first program on a first device may trigger a timing marker on the same cycle as a second program on a second device when the devices'hardware-aligned counters 515 are synchronized. In some instances, these timing markers may be used to synchronize software counters 516 of both devices. For example, in some instances, timing differences between the timing markers may correspond to a time difference indicative of a degree to which the two devices are out of synchronization, and synchronization can include adjusting a timing of one or more operations based on the time difference. For example, in some instances, a software-aligned counter 516 can perform one or more delay operations at each of a plurality of timing markers, and a length of the delay can be adjusted based at least in part on a time difference between the first and second device at the timing marker. However, same-cycle timing is not required; for example, in some instances, a pair of timing markers may be offset by a known number of cycles, which may be compensated for during the synchronization process (e.g., by using different fixed delays, etc.).

In some instances, a timing difference (e.g., number of cycles, etc.) between timing markers may be constrained within a range. For example, a minimum time difference between timing markers in a first and second device may be based on a time to communicate information between the devices (e.g., a number of cycles greater than a message latency), and a maximum time difference between timing markers in the devices may be based on a tolerance of oscillators forming the time base on each processor device 501 (e.g., if the time difference increases beyond a threshold for a given time base tolerance, it may become more difficult or impossible for the processor devices 501 to synchronize for a given fixed delay). The minimum and maximum number of cycles may also be based on the size of a buffer (e.g., a first in first out (FIFO) memory) in each chip-to-chip communication circuit, for example.

In some instances, synchronizing hardware-aligned counters 515 of a pair of devices can include sending, by a first device at a first time t₀, a timing reference; and receiving, at a second time t₁ by a second device, the timing reference. In some instances, the latency of such a transmission may be characterized and designed to be a known time delay Δt=t₁−t₀. In such instances, synchronizing the pair of devices can include setting, by the second device, a hardware-aligned counter 515 to a value of (t₀+Δt) such that the hardware-aligned counters 515 of both devices are synchronized.

In some instances, although the first and second devices can be architecturally similar (e.g., same) or different, synchronizing the devices can include, for example, assigning a first device as a designated sender device to send timing data, and designating a second device as a designated receiver device to receive timing data and adjust a timing of the receiver device's operations based on the timing data.

In some instances, software-aligned counters 516 can be synchronized in a manner similar to synchronization of hardware-aligned counters 515. For example, in some instances, a software-aligned counter 516 can include or implement one or more timing triggers comprising one or more delays (e.g., no-operation (NOP) delays, etc.), wherein a plurality of devices are configured to perform a synchronized delay, such that one or more operations performed after the synchronized delay may be synchronized. For example, in some instances, a first device may send timing data to a second device at t0; and perform a predefined delay operation until t1. A second device may receive the timing data at (t0+Δt); and determine, based on the timing data, an amount of delay (e.g., number of clock cycles, etc.) to cause the second device to resume operations at t1.

In some instances, synchronization can include fine synchronization (e.g., as described above), coarse synchronization, or both. For example, during various points in operation, the first and second processor devices 501 may be far out of sync. For example, during startup or after a restart (collectively, a “reset”), a set (e.g., pair, etc.) of devices may perform a coarse synchronization (e.g., using a 20-bit digital counter, etc.) to bring the time bases close enough so they can be maintained in alignment using the techniques described above (e.g., within a resolution of the hardware and software counters, such as 8 bits).

In some instances, synchronizing a number of devices greater than two can include performing similar operations with more than two devices, such as pairwise synchronizations at staggered times, such as pairwise synchronization of a processor device 501 with each of a plurality of neighbors in a chip-to-chip communication topology at a plurality of respective times; one-to-many (e.g., one-to-all, etc.) broadcasting of timing data; pairwise propagation of timing data between pairs of devices according to a propagation pattern or communication topology; or other mechanism for sending and receiving timing data and updating a timing of operations based on the timing data.

Particular implementations of the subject matter have been described. Other implementations are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

Aspects of the disclosure have been described in terms of illustrative implementations thereof. Numerous other implementations, modifications, or variations within the scope and spirit of the appended claims can occur to persons of ordinary skill in the art from a review of this disclosure. Any and all features in the following claims can be combined or rearranged in any way possible. Accordingly, the scope of the present disclosure is by way of example rather than by way of limitation, and the subject disclosure does not preclude inclusion of such modifications, variations or additions to the present subject matter as would be readily apparent to one of ordinary skill in the art. Moreover, terms are described herein using lists of example elements joined by conjunctions such as “and,” “or,” “but,” etc. It should be understood that such conjunctions are provided for explanatory purposes only. Lists joined by a particular conjunction such as “or,” for example, can refer to “at least one of” or “any combination of” example elements listed therein, with “or” being understood as “and/or” unless otherwise indicated. Also, terms such as “based on” should be understood as “based at least in part on.”

Those of ordinary skill in the art, using the disclosures provided herein, will understand that the elements of any of the claims, operations, or processes discussed herein can be adapted, rearranged, expanded, omitted, combined, or modified in various ways without deviating from the scope of the present disclosure. Some of the claims are described with a letter reference to a claim element for exemplary illustrative purposes and is not meant to be limiting. The letter references do not imply a particular order of operations. For instance, letter identifiers such as (a), (b), (c), . . . , (i), (ii), (iii), . . . , etc. can be used to illustrate operations. Such identifiers are provided for the ease of the reader and do not denote a particular order of steps or operations. An operation illustrated by a list identifier of (a), (i), etc. can be performed before, after, or in parallel with another operation illustrated by a list identifier of (b), (ii), etc.

What is claimed is:

1. An apparatus comprising:
a sliding patch panel comprising:
a plurality of first ports; and
a plurality of second ports, wherein at least one second port of the plurality of second ports is operatively connected to at least one corresponding first port of the plurality of first ports;
wherein the sliding patch panel is configured to slide into and out of one or more slots.

2. The apparatus of claim 1, further comprising slide hardware configured to facilitate sliding of the sliding patch panel.

3. The apparatus of claim 1, wherein the sliding patch panel is configured to slide into and out of one or more server racks.

4. The apparatus of claim 3, wherein the sliding patch panel is configured to slide into and out of a cold-aisle side of the one or more server racks.

5. The apparatus of claim 3, wherein the sliding patch panel is configured to slide into and out of a 1U, 2U, 3U, or 4U server rack slot.

6. The apparatus of claim 1, wherein each of the plurality of first ports is located on a first side of the sliding patch panel, wherein each of the plurality of second ports is located on a second side of the sliding patch panel, and wherein the sliding patch panel is configured to slide into and out of the one or more slots with the first side facing upward.

7. The apparatus of claim 1, wherein the plurality of first ports comprises one or more first optical ports, and wherein the plurality of second ports comprises one or more second optical ports.

8. The apparatus of claim 1, further comprising frame hardware configured to receive the sliding patch panel.

9. The apparatus of claim 8, wherein the frame hardware is configured to be inserted into a 1U, 2U, 3U, or 4U server rack slot.

10. The apparatus of claim 1, wherein the sliding patch panel is horizontally oriented and dimensioned to fit within a 1U, 2U, 3U, or 4U server rack slot.

11. A computing system comprising:
a plurality of computing devices;
a rack configured to accept the plurality of computing devices; and
a sliding patch panel configured to slide into and out of the rack, the sliding patch panel comprising a plurality of first ports and a plurality of second ports.

12. The computing system of claim 11, further comprising:
a plurality of first cables, each first cable connecting a respective second port of the plurality of second ports to a respective third port of the plurality of computing devices; and
one or more second cables, each second cable connecting a pair of first ports of the plurality of first ports.

13. The computing system of claim 12, wherein the one or more second cables are located on a top side of the sliding patch panel.

14. The computing system of claim 11, further comprising slide hardware configured to facilitate sliding of the sliding patch panel.

15. The computing system of claim 11, further comprising one or more prebuilt link panels each comprising a plurality of communication channels, wherein at least one communication channel of the plurality of communication channels connects a respective pair of first ports of the plurality of first ports.

16. The computing system of claim 11, wherein the sliding patch panel is configured to slide into and out of a cold-aisle side of the rack.

17. A method for reconfiguring a network topology of a network of computing devices, comprising:
sliding, from a slot in a server rack configured to hold a plurality of computing devices of the network of computing devices, a sliding patch panel comprising a plurality of first ports and a plurality of second ports, wherein at least one port of the plurality of second ports is operatively connected to one or more computing devices of the network of computing devices; and
connecting or disconnecting at least one pair of first ports of the plurality of first ports.

18. The method of claim 17, wherein sliding the sliding patch panel from the slot comprises sliding the sliding patch panel toward a cold-aisle side of the server rack.

19. The method of claim 17, wherein the at least one pair of first ports is located on a top side of the sliding patch panel, and wherein at least one port of the plurality of second ports is located on a bottom side of the sliding patch panel.

20. The method of claim 17, wherein connecting or disconnecting the at least one pair of first ports comprises connecting or disconnecting a prebuilt link panel comprising a plurality of communication channels, wherein at least one communication channel of the plurality of communication channels connects the at least one pair of first ports.
